(19) United States
(12) Patent Application Publication
(10) Pub. No.: US 2026/0062789 A1
(43) Pub. Date: Mar. 5, 2026

(54) DEPOSITION MASK

(71) Applicant: Samsung Display Co., LTD., Yongin-si (KR)

(72) Inventor: Jin Yong LEE, Yongin-si (KR)

(21) Appl. No.: 19/198,340

(22) Filed: May 5, 2025

(30) Foreign Application Priority Data
Sep. 4, 2024 (KR) 10-2024-0119936

(51) Int. Cl. C23C 14/04; H10K 71/16

(52) U.S. Cl. CPC C23C 14/042; H10K 71/166

(57) ABSTRACT

A deposition mask includes a mask frame in which a cell opening is formed, a membrane disposed on top of the mask frame, and a magnetic layer disposed to cover at least a portion of the membrane.

This application claims priority to Korean Patent Application No. 10-2024-0119936, filed on Sep. 4, 2024, and all the benefits accruing therefrom under 35 U.S.C. § 119, the content of which in its entirety is herein incorporated by reference.

### BACKGROUND

### 1. Field

The present disclosure relates to a deposition mask.

### 2. Description of the Related Art

A head mounted display (HMD) is an image display device worn on a user's head in the form of glasses or a helmet so that a focus is formed at a distance close to a user's eyes. For example, the head mounted display may implement virtual reality (VR) or augmented reality (AR).

The head mounted display enlarges and displays an image displayed by a small-sized display device by using a plurality of lenses. Therefore, a display device applied to the head mounted display needs to provide an image of high resolution, for example, an image having resolution of 3000 Pixels per Inch (PPI) or more. To this end, an Organic Light Emitting Diode on Silicon (OLEDoS), which is a small-sized organic light emitting display device of high resolution, is being used as a display device applied to a head mounted display. The OLEDoS is a device that displays images by disposing an organic light emitting diode (OLED) on a semiconductor wafer substrate including a Complementary Metal Oxide Semiconductor (CMOS).

In order to manufacture a high-resolution display panel of 3000 PPI or more, a high-resolution deposition mask is required. For example, the deposition mask may be manufactured by forming a membrane having a plurality of pixel openings on a substrate like a silicon wafer, and partially etching the substrate to form cell openings exposing the pixel openings.

The deposition mask may be used in a deposition process for forming organic light emitting layers on a backplane substrate. While the deposition process is performed, the backplane substrate may be disposed on the deposition mask, and a deposition source for providing a vapor phase deposition material of may be disposed on below the mask. The vapor phase deposition material may be deposited on the backplane substrate through pixel openings of the deposition mask.

### SUMMARY

Aspects of the invention provide a deposition mask capable of improving a deposition precision of an organic light emitting layer deposited on a backplane substrate.

However, aspects of the invention are not restricted to those set forth herein. The above and other aspects of the invention will become more apparent to one of ordinary skill in the art to which the invention pertains by referencing the detailed description of the present disclosure given below.

According to an aspect of the invention, a deposition mask includes a mask frame in which a cell opening is formed, a membrane disposed on top of the mask frame, and a magnetic layer disposed to cover at least a portion of the membrane.

In an embodiment, the membrane is partitioned in a mask cell area disposed on the top portion of the cell opening, and a grid area disposed on the top portion of the mask frame except the cell opening, and the magnetic layer is disposed on the mask cell area.

In an embodiment, in the mask cell area, a plurality of pixel openings penetrating the membrane and the magnetic layer is formed.

In an embodiment, the membrane includes an inorganic film layer disposed on the top portion of the mask frame, and a nitride layer disposed on the top portion of the inorganic film layer, wherein the magnetic layer is disposed on the top portion of the nitride layer.

In an embodiment, the thickness of the magnetic layer is thinner than the thickness of the inorganic film layer or the thickness of the nitride layer.

In an embodiment, the magnetic layer is formed in the thickness of about 50 nm to about 100 nm.

In an embodiment, the magnetic layer includes at least one or more of nickel (Ni), cobalt (Co), and iron (Fe).

In an embodiment, the magnetic layer has a relative magnetic permeability of about 330 or less.

In an embodiment, the deposition mask further includes a magnetic plate disposed, to cover at least a portion of the membrane, in the grid area.

In an embodiment, the magnetic plate is disposed on the top portion of the nitride layer.

In an embodiment, the thickness of the magnetic plate is thinner than the thickness of the inorganic film layer or the thickness of the nitride layer.

In an embodiment, the magnetic plate is formed in the thickness of about 50 nm to about 100 nm.

In an embodiment, the thickness of the magnetic plate corresponds to the thickness of the magnetic layer.

In an embodiment, the magnetic plate includes at least one or more of nickel (Ni), cobalt (Co), and iron (Fe).

In an embodiment, the magnetic plate has a relative magnetic permeability of about 330 or less.

In an embodiment, in the mask cell area, a plurality of pixel openings penetrating the membrane is formed, and the magnetic layer surrounds the membrane so that a portion thereof is in contact with the pixel opening.

In an embodiment, the membrane includes an inorganic film layer disposed on the top portion of the mask frame, and a nitride layer disposed on the top portion of the inorganic film layer, wherein the magnetic layer includes a first magnetic layer disposed on the top portion of the nitride layer, a second magnetic layer extended from the first magnetic layer to the lower portion, and a third magnetic layer disposed on the lower portion of the inorganic film layer and connected to the second magnetic layer.

In an embodiment, the thickness of the first magnetic layer is thicker than the thickness of the second magnetic layer or the thickness of the third magnetic layer.

In an embodiment, the deposition mask further includes a magnetic plate, disposed on the top portion of the nitride layer, in the grid area, wherein the thickness of the magnetic plate corresponds to the thickness of the first magnet layer.

In an embodiment, the deposition mask further includes a first rear inorganic film layer disposed on the lower portion of the mask frame and in which a first rear opening is formed, and a second rear inorganic film layer disposed on the lower portion of the first rear inorganic film layer and in which a second rear opening is formed, wherein the first rear opening and the second rear opening are disposed on the cell opening.

According to the deposition mask, according to an embodiment, there is an effect of improving a deposition precision of an organic light emitting layer deposited on a backplane substrate by increasing adhesion between the membrane and the backplane substrate by placing a magnetic layer on top portion of a membrane.

The effects, according to an embodiments, are not limited to those mentioned above and more various effects are included in the following description of the invention.

### BRIEF DESCRIPTION OF THE DRAWINGS

The above and other aspects and features of the invention will become more apparent by describing in detail example embodiments thereof with reference to the attached drawings, in which:

FIG. 1 is a schematic exploded perspective view showing a display device, according to an embodiment;

FIG. 2 is a schematic plan view for illustrating a display device shown in FIG. 1, according to an embodiment;

FIG. 3 is an schematic equivalent circuit diagram showing an example of a first sub-pixel shown in FIG. 2, according to an embodiment;

FIG. 4 is a plan view showing an example of a display panel shown in FIG. 1, according to an embodiment;

FIG. 5 is an enlarged plan view illustrating an example of a display area of FIG. 4, according to an embodiment;

FIG. 6 is an enlarged plan view illustrating another example of a display area of FIG. 4, according to an embodiment;

FIG. 7 is a cross-sectional view showing an example of a display panel cut along line I1-I1′ of FIG. 5, according to an embodiment;

FIG. 8 is a cross-sectional view showing another example of a display panel cut along line I1-I1′ of FIG. 5, according to an embodiment;

FIG. 9 is a perspective view illustrating an example of a head mounted display, according to an embodiment;

FIG. 10 is an exploded perspective view illustrating the head mounted display device of FIG. 9, according to an embodiment;

FIG. 11 is a perspective view showing another example of a head mounted display device, according to an embodiment;

FIG. 12 is a diagram showing a deposition device, according to an embodiment;

FIG. 13 is a bottom view showing a backplane substrate shown in FIG. 12, according to an embodiment;

FIG. 14 is a plan view showing a deposition mask according to one embodiment, according to an embodiment;

FIG. 15 is an enlarged plan view showing mask cell areas illustrated in FIG. 14, according to an embodiment;

FIG. 16 is a cross-sectional view showing a first embodiment of a deposition mask cut along line I2-I2′ of FIG. 15, according to an embodiment;

FIG. 17 is a cross-sectional view showing a state in which a magnetic plate is disposed on top of a membrane, according to an embodiment;

FIG. 18 is a cross-sectional view showing a deposition mask cut along line I2-I2′ of FIG. 15, according to another embodiment;

FIG. 19 is a partial enlarged view of FIG. 18, according to an embodiment;

FIG. 20 is a cross-sectional view showing a state in which the magnetic plate is disposed on top of the membrane in FIG. 18, according to an embodiment;

FIG. 21 is a graph showing magnetic force generated compared to the relative magnetic permeability of a magnetic layer of the deposition mask, according to an embodiment; and

FIG. 22 is a graph showing magnetic force generated compared to the relative magnetic permeability of a magnetic plate of the deposition mask, according to an embodiment.

FIG. 23 is a block diagram of an electronic device, according to an embodiment.

FIG. 24 is a schematic diagram of an electronic device according to various embodiments.

### DETAILED DESCRIPTION

Advantages and features of the invention and methods to achieve them will become apparent from the descriptions of example embodiments hereinbelow with reference to the accompanying drawings. However, the invention is not limited to example embodiments disclosed herein but may be implemented in various different ways. The example embodiments are provided for making the disclosure of the invention thorough and for fully conveying the scope of the invention to those skilled in the art. It is to be noted that the scope of the invention is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the invention.

Features of various example embodiments of the present disclosure may be combined partially or totally. As will be clearly appreciated by those skilled in the art, technically various interactions and operations are possible. Various example embodiments can be practiced individually or in combination.

Hereinafter, example embodiments of the invention will be described in detail with reference to the accompanying drawings.

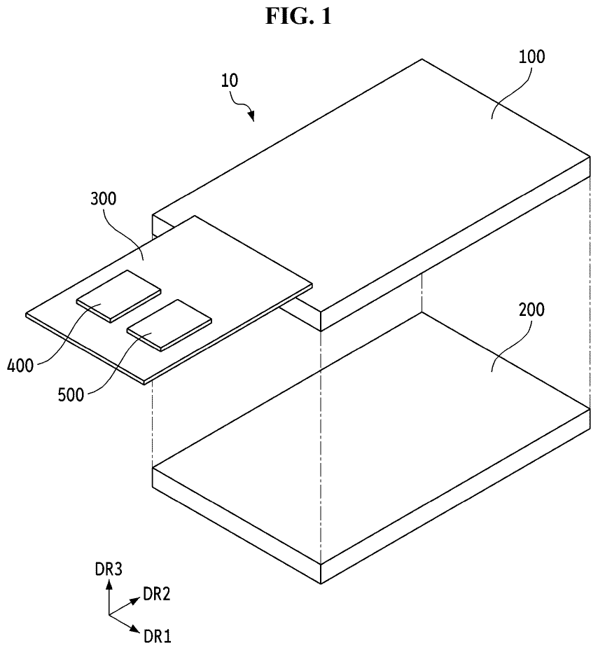

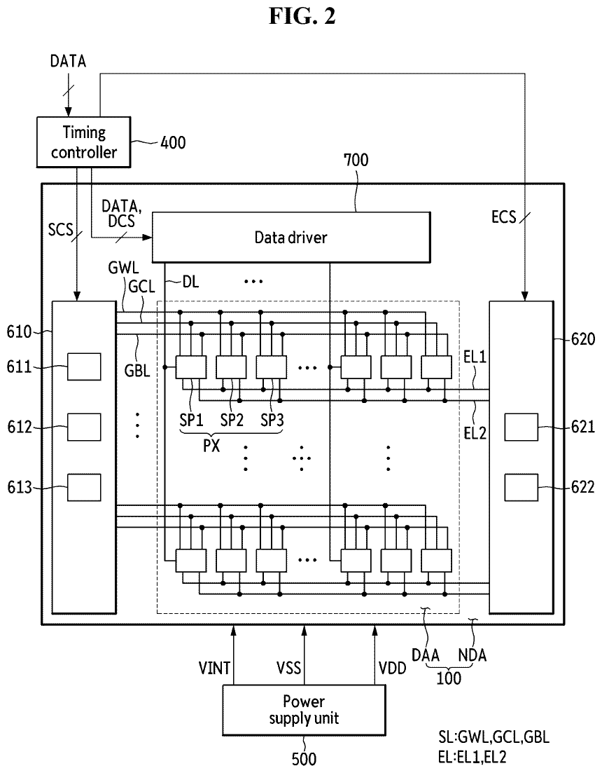

FIG. 1 is a schematic exploded perspective view showing a display device, according to an embodiment. FIG. 2 is a schematic plan view for illustrating a display device shown in FIG. 1, according to an embodiment.

Referring to FIGS. 1 and 2, a display device 10, according to an embodiment, is a device displaying a moving image or a still image. The display device 10, according to an embodiment, may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10, according to an embodiment, may be applied as a display unit of a television, a laptop, a monitor, a billboard, or an Internet-of-Things (IoT) terminal. In another embodiment, the display device 10 may be applied to a smart watch, a watch phone, a head mounted display (HMD) for implementing virtual reality and augmented reality, and the like.

The display device 10, according to an embodiment, includes a display panel 100, a heat dissipation layer 200, a circuit board 300, a timing control circuit 400, and a power supply circuit 500.

In an embodiment, the display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape and may be a shape similar to another polygonal shape, a circular shape, or an elliptical shape. The planar shape of the display device 10 may conform to the planar shape of the display panel 100, but the invention is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

In an embodiment, the plurality of pixels PX may be disposed in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

In an embodiment, the plurality of scan lines SL include a plurality of write scan lines GWL, a plurality of control scan lines GCL, and a plurality of bias scan lines GBL. The plurality of emission control lines ECL include a plurality of first emission control lines ECL1 and a plurality of second emission control lines ECL2.

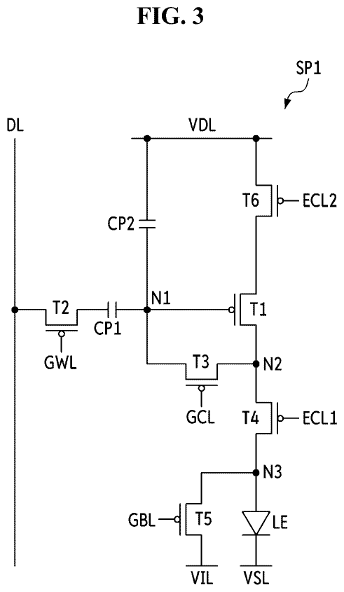

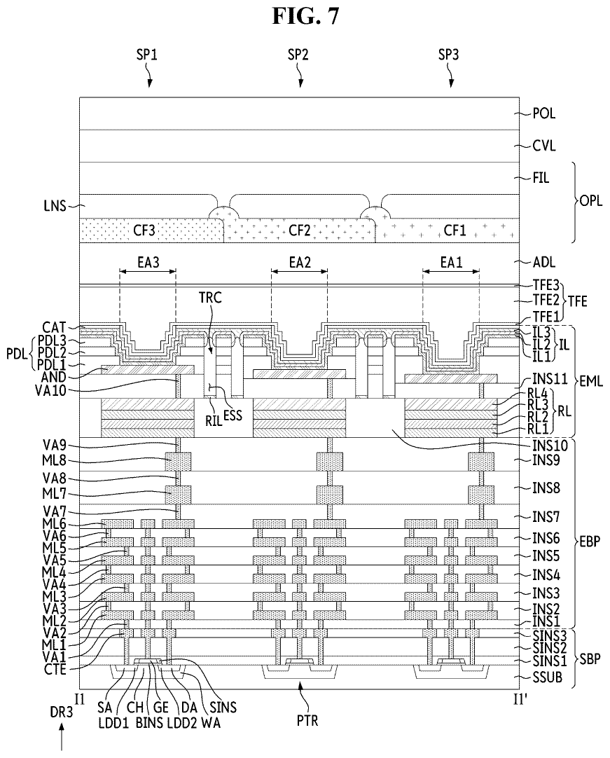

In an embodiment, the plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS), but the invention is not limited thereto.

In an embodiment, each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL and emit light from the light emitting element according to the data voltage.

In an embodiment, the scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS, but the invention is not limited thereto.

In an embodiment, the scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

In an embodiment, the emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

In an embodiment, the data driver 700 may include a plurality of data transistors, and the plurality of data transistors may be formed on the semiconductor substrate SSUB (see FIG. 7) through a semiconductor process. For example, the plurality of data transistors may be formed of CMOS, but the invention is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

In an embodiment, the heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

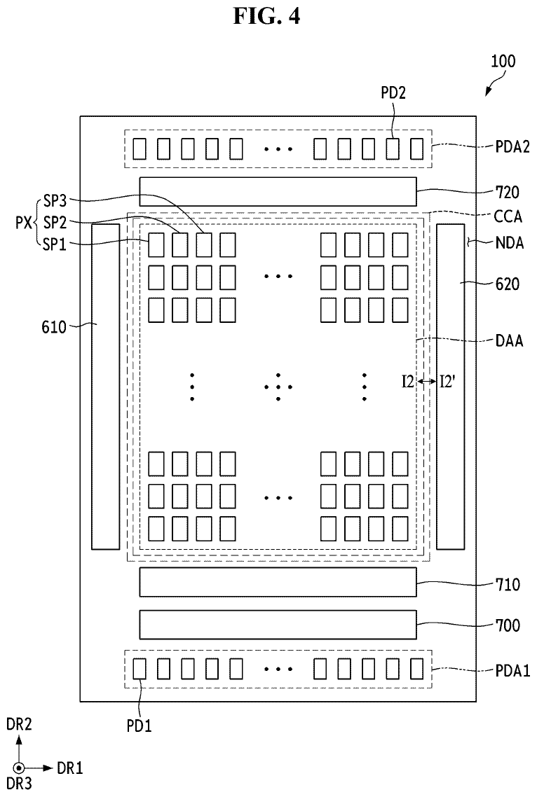

In an embodiment, the circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

In an embodiment, the timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

In an embodiment, the power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

In an embodiment, each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS, but the present disclosure is not limited thereto. Each of the timing control circuit 400 and the power supply circuit 500 may be disposed between the data driver 700 and the first pad portion PDA1 (see FIG. 4).

FIG. 3 is an equivalent circuit diagram showing an example of a first sub-pixel shown in FIG. 2, according to an embodiment.

In an embodiment and referring to FIG. 3, a first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In an embodiment, the first sub-pixel SP1 includes a plurality of transistors T1 to T6, a light-emitting element LE, a first capacitor CP1, and a second capacitor CP2.

The light emitting element LE emits light in response to a driving flowing through the channel of a first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode thereof according to a voltage applied to the gate electrode thereof.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between a first node N1 and a second node N2. The third transistor T3 is turned on by the write control signal of the write control line GCL to connect the first node N1 to the second node N2. For this reason, in case, the gate electrode and the source electrode of the first transistor T1 are connected, the first transistor T1 may operate like a diode.

A fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

A sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

In an embodiment, each of the transistors T1 to T6 may be a metal-oxide-semiconductor field effect transistor (MOSFET). For example, each of the transistors T1 to T6 may be a P-type MOSFET, but the invention is not limited thereto. Each of the transistors T1 to T6 may be an N-type MOSFET. In another embodiment, some of the transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a schematic plan view showing an example of a display panel shown in FIG. 1, according to an embodiment.

In an embodiment and referring to FIG. 4, the display area DAA of the display panel 100 includes the plurality of pixels PX arranged in a matrix form. The non-display area NDA of the display panel 100, according to an embodiment, includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. However, the invention is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA may be disposed on the outer side of the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process or may be connected to a circuit board for inspection. The circuit board for inspection may be a printed circuit board made of a rigid material, or a flexible printed circuit board made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

In an embodiment, t cathode connection part CCA may be an area where a second electrode CAT (see FIG. 7) of a display element layer EML (see FIG. 7) is connected to the first driving voltage line VSL of the non-display area NDA. The cathode connection part CCA may be disposed outside at least one side of the display area DAA. For example, the cathode connection part CCA may be disposed outside at least one side of the display area DAA among the left side, right side, upper side, and lower side of the display area DAA. In another embodiment, the cathode connection part CCA may be disposed to surround the display area DAA as shown in FIG. 4 in order to minimize deviations of the first driving voltage VSS caused by voltage drop (IR drop) or voltage rise (IR rising) of the second electrode CAT in the display area DAA.

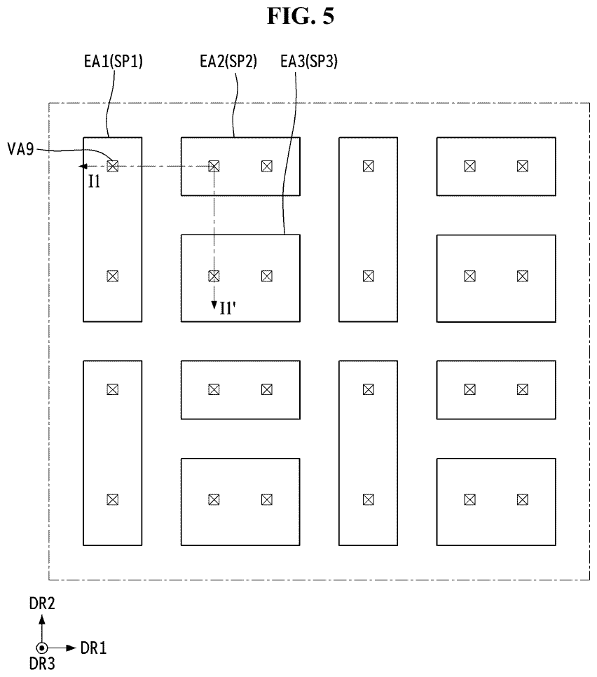

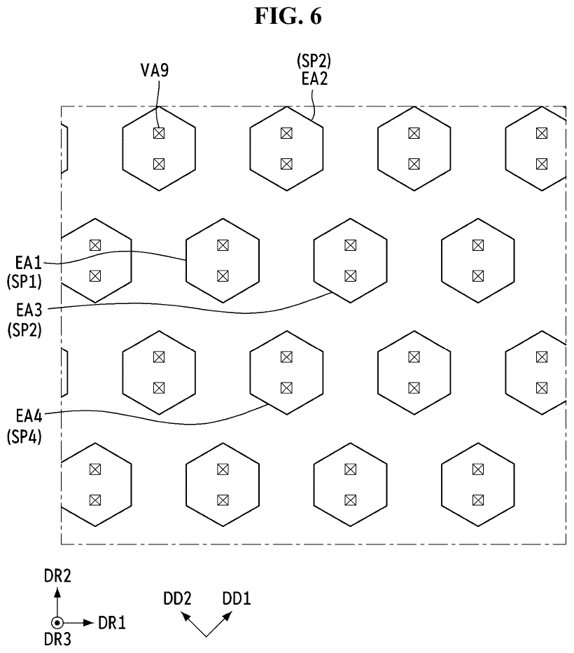

FIG. 5 is an enlarged plan view illustrating an example of a display area of FIG. 4, according to an embodiment. FIG. 6 is an enlarged plan view illustrating another example of a display area of FIG. 4, according to an embodiment.

In an embodiment and referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 5 and 6, but the invention is not limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

In another embodiment, as shown in FIG. 6, the emission areas EA1, EA2, EA3, and EA4 may have a hexagonal shape in a plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

In an embodiment, the first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to about 460 nm, the green wavelength band may be a wavelength band of light whose main peak wavelength is in the range of approximately 480 nm to about 560 nm, and the red wavelength band may be a wavelength band of light whose main peak wavelength is in the range of approximately 600 nm to about 750 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the present disclosure is not limited thereto.

The emission areas of the plurality of pixels PX may be disposed in a stripe structure where the emission areas are arranged in the first direction DR1, in a PenTile® structure where the emission areas EA1, EA2, EA3, and EA4 are arranged in a rhombus shape as shown in FIG. 6, or in a hexagonal structure where the emission areas are arranged in a hexagonal shape.

FIG. 7 is a cross-sectional view showing an example of a display panel cut along line I1-I1′ of FIG. 5, according to an embodiment.

In an embodiment and referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. In another embodiment, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

In an embodiment, each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

In an embodiment, each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

In an embodiment, a first semiconductor insulating film SINS1 may be disposed on the semiconductor substrate SSUB. A second semiconductor insulating film SINS2 may be disposed on the first semiconductor insulating film SINS1.

In an embodiment, the plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, a third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but the present disclosure is not limited thereto.

In an embodiment, the semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

In an embodiment, the light emitting element backplane EBP includes a plurality of conductive layers ML1 to ML8, a plurality of vias VA1 to VA9, and a plurality of insulating films INS1 to INS11. In addition, the light emitting element backplane EBP includes a plurality of insulating films INS1 to INS9 disposed between the conductive layers ML1 to ML8.

The insulating films INS1 to INS8 serve to insulate the conductive layers ML1 to ML8. The conductive layers ML1 to ML8 serve to connect the plurality of contact terminals CTE exposed from the semiconductor backplane SBP to thereby implement the circuit of the first sub-pixel SP1 shown in FIG. 3.

For example, the transistors T1 to T6 are merely formed in the semiconductor backplane SBP, and the connection of the transistors T1 to T6 and the first and second capacitors C1 and C2 is accomplished through the conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the conductive layers ML1 to ML8.

The conductive layers ML1 to ML8 and the vias VA1 to VA8 may be formed of substantially the same material. The conductive layers ML1 to ML8 and the vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The vias VA1 to VA8 may be made of substantially the same material. The insulating films INS1 to INS8 may be formed of a silicon oxide (SiOx)-based inorganic film, but the invention is not limited thereto.

In an embodiment, a ninth insulating film INS9 may be disposed on the eighth insulating film INS8 and the eighth conductive layer ML8. The ninth insulating film INS9 may be formed of a silicon oxide (SiOx)-based inorganic film, but the invention is not limited thereto.

Each of the ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, the display element layer EML may be disposed on the light emitting element backplane EBP. The display element layer EML may include insulating films INS10 and INS11, a reflective electrode RL, the first electrodes AND, a light emitting stack IL, the second electrode CAT, a pixel defining film PDL, and a plurality of trenches TRC.

In an embodiment, the reflective electrode RL may be disposed on the ninth insulating film INS9. The reflective electrode RL may include at least one reflective electrode RL1, RL2, RL3, and RL4. For example, the reflective electrode RL may include the reflective electrodes RL1, RL2, RL3, and RL4 as shown in FIG. 7.

The first reflective electrodes RL1 may be disposed on the ninth insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth insulating film INS10 may be disposed on the ninth insulating film INS9. The tenth insulating film INS10 may be disposed between the reflective electrodes RL adjacent to each other. The tenth insulating film INS10 may be a film for flattening a stepped portion caused by the reflective electrodes RL. The eleventh insulating film INS11 may be disposed on the tenth insulating film INS10 and the reflective electrode RL.

The tenth insulating film INS10 and the eleventh insulating film INS11 may be formed of a silicon oxide (SiOx)-based inorganic film, but the invention is not limited thereto.

The eleventh insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh insulating film INS11 may be set for each of the first sub-pixel SP1, the second sub-pixel SP2, and the third sub-pixel SP3.

For example, as shown in FIG. 7, the thickness of the eleventh insulating film INS11 in the first sub-pixel SP1 may be greater than the thickness of the eleventh insulating film INS11 in the second sub-pixel SP2, and the thickness of the eleventh insulating film INS11 in the second sub-pixel SP2 may be greater than the thickness of the eleventh insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh insulating film INS11 and be connected to the exposed fourth-reflective electrodes RL4. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh insulating film INS11 and connected to the tenth via VA10. The first electrode AND of each of the light emitting elements LE may be connected to the drain region DA or source region SA of the pixel transistor PTR through the tenth via VA10, the reflective electrode RL, the vias VA1 to VA9, the metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

In an embodiment, the pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

In an embodiment, the pixel defining film PDL may include pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film. In another embodiment, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In an embodiment and in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

In an embodiment, each of the plurality of trenches TRC may penetrate the first pixel defining film PDL1, the second pixel defining film PDL2, and the third pixel defining film PDL3. The eleventh insulating film INS11 may be partially recessed at each of the plurality of trenches TRC.

In an embodiment, at least one trench TRC may be disposed between the neighboring sub-pixels SP1, SP2, and SP3. Although FIG. 7 illustrates that two trenches TRC are disposed between the neighboring sub-pixels SP1, SP2, and SP3, the invention is not limited thereto.

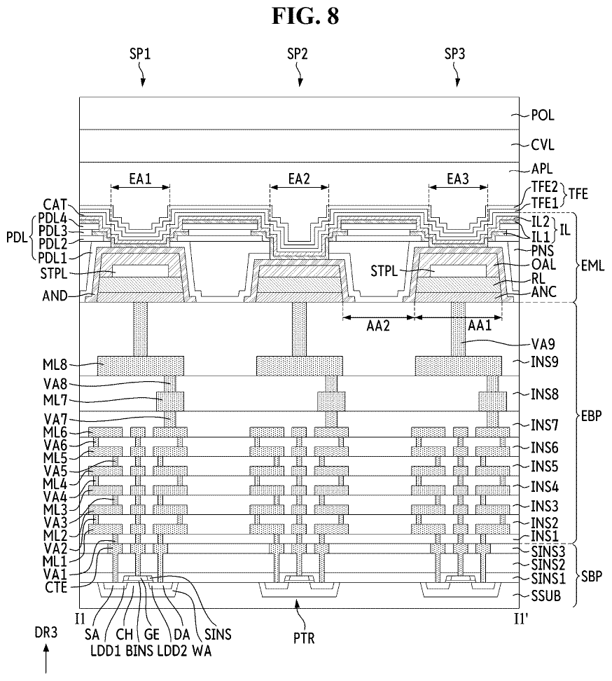

In an embodiment, the light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but the invention is not limited thereto. For example, the light emitting stack IL may have a two-tandem structure including two stack layers as shown in FIG. 8.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

In an embodiment, a first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

In an embodiment, a second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

In an embodiment, the first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film RIL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the hole transport layers, the first charge generation layer, and the second charge generation layer of the stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In order to stably cut off the stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse-tapered partition wall may be disposed on the pixel defining film PDL.

In addition, FIG. 7 illustrates an embodiment where the light emitting stack IL that emits light is disposed in the first emission area EA1, the second emission area EA2, and the third emission area EA3, but the invention is not limited thereto. For example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, color filters CF1, CF2, and CF3 of the optical layer OPL may be omitted.

In an embodiment, the second electrode CAT may be disposed on the light emitting stack IL. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the sub-pixels SP1, SP2, and SP3 due to a micro-cavity effect.

In an embodiment, the encapsulation layer TFE may be disposed on the display element layer EML. The encapsulation layer TFE may include at least one inorganic film TFE1 and TFE3 to reduce or prevent oxygen or moisture from permeating into the display element layer EML. For example, the first encapsulation inorganic film TFE1 may be disposed on the second electrode CAT, and the second encapsulation inorganic film TFE3 may be disposed on the first encapsulation inorganic film TFE1. The first encapsulation inorganic film TFE1 and the second encapsulation inorganic film TFE3 may be formed of multiple layers in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In an embodiment, the encapsulation layer TFE may include at least one encapsulation organic film TFE2 to protect the display element layer EML from foreign substances such as dust. For example, the encapsulation organic film TFE2 may be disposed between the first encapsulation inorganic film TFE1 and the second encapsulation inorganic film TFE3. The encapsulation organic film TFE2 may be a monomer. In another embodiment, the encapsulation organic film TFE2 may be an organic film such as acryl resin, epoxy resin, phenolic resin, polyamide resin, polyimide resin or the like.

In an embodiment, an adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

In an embodiment, the optical layer OPL includes a plurality of color filters CF1, CF2, and CF3, a plurality of lenses LNS, and a filling layer FIL. The plurality of color filters CF1, CF2, and CF3 may include the color filters CF1, CF2, and CF3. The color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be approximately 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be approximately 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be approximately 600 nm to about 750 nm. Thus, the third color filter CF3 may transmit light of the third color among light emitted from the third emission area EA3.

In an embodiment, the plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

In an embodiment, the filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

In an embodiment, the cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

In an embodiment, the polarizing plate may be disposed on one surface of the cover layer CVL. The polarizing plate may be a structure for preventing visibility degradation caused by reflection of external light. The polarizing plate may include a linear polarizing plate and a phase retardation film. For example, the phase retardation film may be a N4 plate (quarter-wave plate), but the invention is not limited thereto. However, when visibility degradation caused by reflection of external light is sufficiently overcome by the color filters CF1, CF2, and CF3, the polarizing plate may be omitted.

FIG. 8 is a cross-sectional view showing another example of a display panel cut along line I1-I1′ of FIG. 5, according to an embodiment.

An embodiment of FIG. 8 differs from the embodiment of FIG. 7 in that the first electrode AND of each of the light emitting elements LE is electrically connected by being in contact with a side surface of a connection electrode ANC connected to the eighth conductive layer ML8. In addition, the embodiment of FIG. 8 differs from the embodiment of FIG. 7 in that the trench TRC is omitted, and instead, a third pixel defining film PDL3 and a fourth pixel defining film PDL4 have a cross-sectional structure in a shape of an caves or a mushroom shape. In the embodiment of FIG. 8, a description overlapping the embodiment of FIG. 7 will be omitted.

In an embodiment and referring to FIG. 8, a plurality of connection electrodes ANC may be respectively disposed on first portions AA1 of the ninth insulating film INS9. Each of the plurality of connection electrodes ANC may be disposed on the first portion AA1 of the ninth insulating film INS9 corresponding thereto. The plurality of connection electrodes ANC may be formed of an alloy including any one of copper (Cu), aluminum (Al), tungsten (W), molybdenum (Mo), chromium (Cr), gold (Au), titanium (Ti), nickel (Ni), and neodymium (Nd), or transparent conductive oxide. For example, the plurality of connection electrodes ANC may include titanium (Ti), titanium nitride (TiN), indium tin oxide (ITO), or indium zinc oxide (IZO), but the but the invention is not limited thereto.

In an embodiment, a plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, each of the plurality of reflective electrodes RL may include aluminum (Al) having high reflectivity.

In an embodiment, a plurality of optical auxiliary films OAL may be respectively disposed on the plurality of reflective electrodes RL. Each of plurality of optical auxiliary films OAL may be disposed on the reflective electrode RL corresponding thereto. The plurality of optical auxiliary films OAL may be formed of a silicon oxide (SiOx)-based inorganic film, but the but the invention is not limited thereto.

In an embodiment, a step layer STPL may be disposed on the reflective electrode RL in each of the first emission area EA1 and the third emission area EA3, and the optical auxiliary film OAL may be disposed on the step layer STPL. In the second emission area EA2, only the optical auxiliary film OAL may be disposed on the reflective electrode RL. The thicknesses of the optical auxiliary film OAL in the first emission area EA1, the second emission area EA2, and the third emission area EA3 may be substantially the same.

In an embodiment, due to the step layer STPL, a distance between the reflective electrode RL and the first electrode AND in the first emission area EA1 and the third emission area EA3 may be greater than a distance between the reflective electrode RL and the first electrode AND in the second emission area EA2. The thickness of the step layer STPL and the thickness of the optical auxiliary film OAL may be set by considering the wavelength and resonance distance of light emitted from the first stack layer IL1 of the light emitting stack IL and the wavelength and resonance distance of light emitted from the second stack layer IL2 thereof.

Each of the light emitting elements LE may include a first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary film OAL are sequentially stacked, the first electrode AND of each of the light emitting elements LE may be disposed on upper and side surfaces of the optical auxiliary film OAL, a side surface of the reflective electrode RL, and a side surface of the connection electrode ANC. As a result, the first electrode AND of each of the light emitting elements LE may be electrically connected by being in contact with the side surface of the reflective electrode RL and the side surface of the connection electrode ANC. Therefore, since the mask process may be reduced compared to when the first electrode AND of each of the light emitting elements LE is connected to the exposed reflective electrode RL through a through hole penetrating through the optical auxiliary film OAL, manufacturing costs may be reduced and manufacturing efficiency may be increased.

The first electrode AND of each of the light emitting elements LE may be connected to the drain region DA or the source region SA of the pixel transistor PTR through the connection electrode ANC, the vias VA1 to VA9, the conductive layers ML1 to ML8, and the contact terminal CTE.

The ninth insulating film INS9 may include a first portion AA1 that overlaps the connection electrode ANC in the third direction DR3 and a second portion AA2 that does not overlap the connection electrode ANC in the third direction DR3. A thickness of the first portion AA1 and a thickness of the second portion AA2 of the ninth insulating film INS9 may be substantially the same.

In another embodiment, the thickness of the first portion AA1 of the ninth insulating film INS9 may be greater than the thickness of the second portion AA2. In this case, a side surface of the first portion AA1 of the ninth insulating film INS9 may be exposed, and the first electrode AND of each of the light emitting elements LE may be disposed on the exposed side surface of the first portion AA1 of the ninth insulating film INS9.

The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof, or a transparent conductive oxide. For example, the first electrode AND of each of light emitting elements LE may include titanium nitride (TiN), indium tin oxide (ITO), or indium zinc oxide (IZO), but the invention is not limited thereto.

In an embodiment, the pixel defining film PDL may be disposed on a partial area of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3.

The pixel defining film PDL may include pixel defining films PDL1, PDL2, PDL3, and PDL4.

The first pixel defining film PDL1 may be disposed on the first electrode AND of each of the light emitting elements LE. Specifically, the first pixel defining film PDL1 may cover a portion of an upper surface of the first electrode AND disposed on the optical auxiliary film OAL. In addition, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on an upper surface of the second portion AA2 of the ninth insulating film INS9.

A planarization film PNS is a film for planarizing the steps caused by the connection electrode ANC, the reflective electrode RL, and the optical auxiliary film OAL.

In an embodiment, the planarization film PNS may be disposed on the first pixel defining film PDL1 that covers the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth insulating film INS9.

The planarization film PNS may be disposed between the connection electrodes ANC adjacent to each other in the first direction DR1 or the second direction DR2. The planarization film PNS may be disposed between the reflective electrodes RL adjacent to each other in the first direction DR1 or the second direction DR2. The planarization film PNS may be disposed between the optical auxiliary films OAL adjacent to each other in the first direction DR1 or the second direction DR2.

In an embodiment, while there is no step layer STPL in the second emission area EA2, there is a step layer STPL in each of the first emission area EA1 and the third emission area EA3. As a result, the height of the connection electrode ANC, the reflective electrode RL, and the optical auxiliary film OAL in the second emission area EA2 may be smaller than the height of the connection electrode ANC, the reflective electrode RL, the step layer STPL, and the optical auxiliary film OAL in each of the first emission area EA1 and the third emission area EA3. Therefore, the planarization film PNS may cover the upper surface of the first pixel defining film PDL1 disposed on the upper surface of the first electrode AND disposed in the second emission area EA2.

In comparison, an upper surface of the planarization film PNS may be flatly connected to the upper surface of the first electrode AND disposed in the first emission area EA1 and the third emission area EA3. That is, the planarization film PNS may not cover the upper surface of the first pixel defining film PDL1 disposed on the upper surface of the first electrode AND disposed in each of the first emission area EA1 and the third emission area EA3.

In an embodiment, the second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 are formed of a silicon nitride (SiNx)-based inorganic film, while the second pixel defining film PDL2, the fourth pixel defining film PDL4, and the planarization film PNS may be formed of a silicon oxide (SiOx)-based inorganic film. As the first pixel defining film PDL1 is formed of a different material from the planarization film PNS, the first pixel defining film PDL1 may serve as a stopper in a process of chemically and mechanically polishing the planarization film PNS.

When the planarization film PNS and the second pixel defining film PDL2 are identically formed of a silicon oxide (SiOx)-based inorganic film, the planarization film PNS and the second pixel defining film PDL2 may be formed as a single film.

In an embodiment, since a length of the third pixel defining film PDL3 in one direction is smaller than a length of the fourth pixel defining film PDL4 in one direction, a lower surface of the fourth pixel defining film PDL4 may be exposed without being covered by the third pixel defining film PDL3. That is, the third pixel defining film PDL3 and the fourth pixel defining film PDL4 may have a cross-sectional structure in a shape of an caves or a mushroom shape.

In an embodiment, the light emitting stack IL may be disposed on the first electrodes AND and the pixel defining film PDL. The light emitting stack IL may include a first stack layer IL1 and a second stack layer IL2 that emit different lights. When the light emitting stack IL has a two-tandem structure, any one of the first stack layer IL1 and the second stack layer IL2 may emit light including a wavelength range of any one of the first light, the second light, and the third light, and the remaining one may emit light that includes the wavelength ranges of the other two lights. For example, the first stack layer IL1 may emit light that includes a wavelength range of the first light and a wavelength range of the third light, and the second stack layer IL2 may emit light that includes a wavelength range of the second light. Here, the first light may be light of a blue wavelength band, the second light may be light of a green wavelength band, and the third light may be light of a red wavelength band.

In an embodiment, a charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

Since the first stack layer IL1 is not formed on the exposed lower surface of the fourth pixel defining film PDL4 that is not covered by the third pixel defining film PDL3, the first stack layer IL1 may be disconnected by the cross-sectional structure in the shape of an caves or the mushroom shape by the third pixel defining film PDL3 and the fourth pixel defining film PDL4. In this case, the first hole transporting layer of the first stack layer IL1 and the charge generation layer CGL disposed between the first stack layer IL1 and the second stack layer IL2 may also be disconnected. In addition, it is illustrated in FIG. 8 that the second stack layer IL2 is connected without being disconnected, but the second hole transport layer of the second stack layer IL2 may be disconnected, and the second electron transport layer of the second stack layer IL2 may be connected without being disconnected. Therefore, it is possible to prevent leakage current from flowing between the emission areas EA1, EA2, and EA3 adjacent to each other through the first hole transport layer of the first stack layer IL1, the second hole transport layer of the second stack layer IL2, and the charge generation layer CGL. Therefore, it is possible to prevent the light emitting stacks IL in the emission areas EA1, EA2, and EA3 adjacent to each other from being affected by the current and emitting light other than the originally intended light.

FIG. 8 illustrates the two-tandem structure in which the light emitting stack IL includes two stack layers IL1 and IL2, but the invention is not limited thereto. For example, the light emitting stack IL may have a three-tandem structure including three stack layers as illustrated in FIG. 7. In this case, by adjusting the height of the third pixel defining film PDL3, the charge generation layer between the first stack layer IL1 and the second stack layer IL2, and the charge generation layer between the second stack layer IL2 and the third stack layer IL3 may be designed to be disconnected. In another embodiment, as illustrated in FIG. 7, a trench penetrating through the first pixel defining film PDL1, planarization film PNS, the second pixel defining film PDL2, and the third pixel defining film PDL3 may be added. In this case, the trench TRC may penetrate through at least a portion of the ninth insulating film INS9, but the but the invention is not limited thereto.

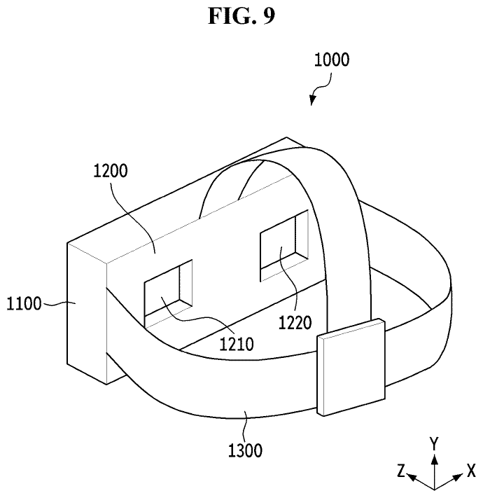

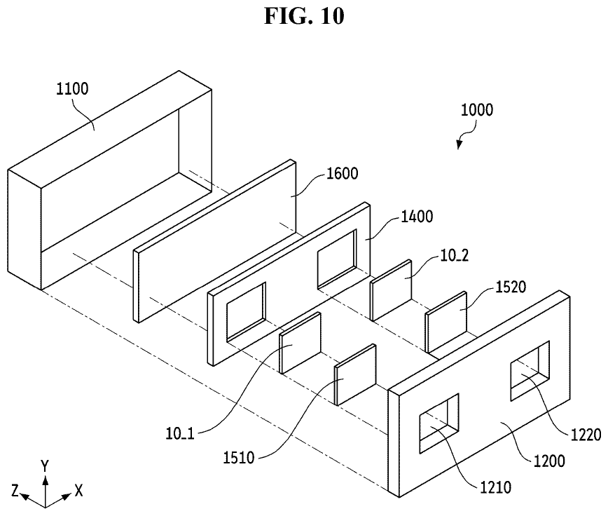

FIG. 9 is a perspective view illustrating an example of a head mounted display, according to an embodiment. FIG. 10 is an exploded perspective view illustrating the head mounted display device of FIG. 9, according to an embodiment.

In an embodiment and referring to FIGS. 9 and 10, a head mounted display 1000 includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 8, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1 and may transmit the digital video data DATA corresponding to a right-eye image optimized for the user's right eye to the second display device 10_2. In an embodiment, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 9 and 10 illustrate that the first eyepiece 1210 and the second eyepiece 1220 are disposed separately, but the invention is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

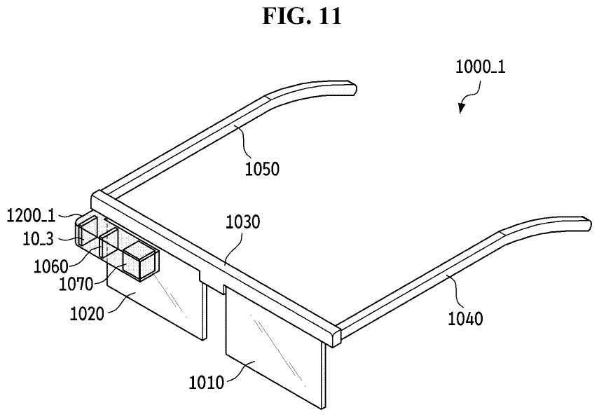

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with an eyeglass frame as shown in FIG. 11 instead of the head mounted band 1300.

FIG. 11 is a perspective view showing another example of a head mounted display device, according to an embodiment.

In an embodiment and referring to FIG. 11, a head mounted display 1000_1 according to one embodiment may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 11 illustrates that the display device housing 1200_1 is disposed at the right end of the support frame 1030, but the invention is not limited thereto. For example, the display device housing 1200_1 may be disposed at the left end of the support frame 1030, and in this case, the image of the display device 10_3 may be provided to the user's left eye. In an embodiment, the display device housing 1200_1 may be disposed at both the left and right ends of the support frame 1030, and in this case, the user may view the image displayed on the display device 10_3 through both the left and right eyes.

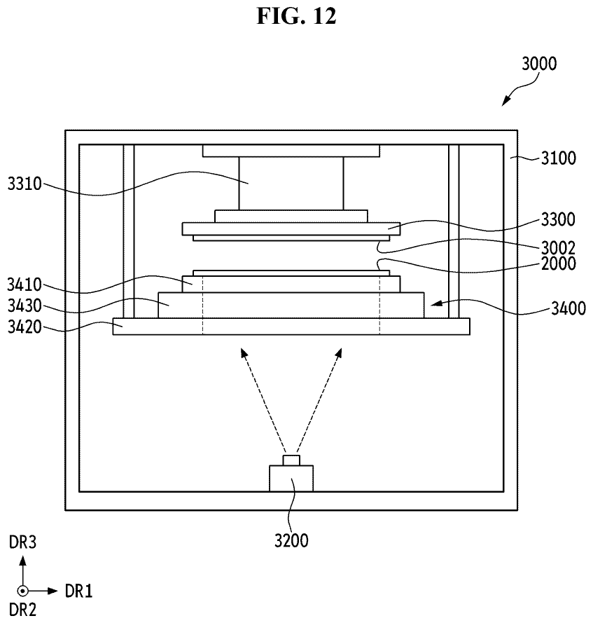

FIG. 12 is a schematic diagram showing a deposition device, according to an embodiment.

In an embodiment and referring to FIG. 12, a deposition device 3000 may be used to form light emitting material layers on a backplane substrate 3002 in a process of manufacturing the display panel 100 (see FIG. 1). For example, as illustrated in FIG. 7, a semiconductor backplane SBP and a light emitting element backplane EBP may be disposed on the backplane substrate 3002, and a reflective electrode RL and a tenth insulating film INS10 may be disposed on the light emitting element backplane EBP. An eleventh insulating film INS11 may be disposed on the tenth insulating film INS10, electrode patterns, for example, anode electrodes AND, may be disposed on the eleventh insulating film INS11, and the anode electrodes AND may be electrically connected to the reflective electrode RL through vias VA10. The deposition device 3000 may be used to form a light emitting stack IL on the electrode patterns.

In an embodiment, the deposition device 3000 may include a deposition source 3200 for providing a vapor deposition material on the backplane substrate 3002, a deposition mask 2000 disposed on the deposition source 3200, and a substrate chuck 3300 that is disposed on the deposition mask 2000 and supports the backplane substrate 3002 so that the backplane substrate 3002 faces the deposition mask 2000. That is, the substrate chuck 3300 may support the backplane substrate 3002 so that the front side of the backplane substrate 3002 faces downward and may position the backplane substrate 3002 on the deposition mask 2000 to perform a deposition process. The substrate chuck 3300 may be supported by a support member 3310, and a permanent magnet (not illustrated) may be disposed inside the support member 3310.

In an embodiment, the deposition source 3200, the deposition mask 2000, and the substrate chuck 3300 may be disposed within a process chamber 3100. The process chamber 3100 may have an internal space, and a deposition process for forming a deposition material layer on the backplane substrate 3002 may be performed in the internal space of the process chamber 3100. Although not illustrated, the process chamber 3100 may be connected to a vacuum pump (not illustrated), and the internal space of the process chamber 3100 may be created into a vacuum atmosphere by the vacuum chamber. An opening (not illustrated) for the entry and exit of the backplane substrate 3002 and the deposition mask 2000 may be provided on one side wall of the process chamber 3100 and may be opened and closed by a gate valve (not illustrated).

A deposition material may be stored within the deposition source 3200. The deposition source 3200 may evaporate a deposition material such as an organic material, an inorganic material, a conductive material, etc. toward the backplane substrate 3002, and the evaporated deposition material may be deposited on the backplane substrate 3002 through the deposition mask 2000. For example, the deposition source 3200 may evaporate an organic material for forming light emitting material layers on the backplane substrate 3002, and the evaporated organic material may be deposited on electrode patterns on the backplane substrate 3002 through the deposition mask 2000.

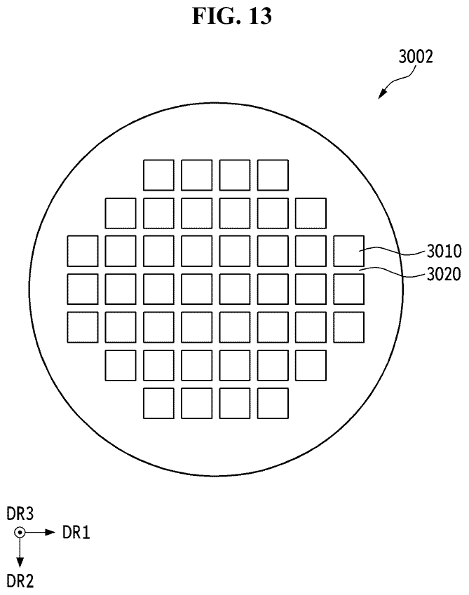

FIG. 13 is a bottom view showing a backplane substrate shown in FIG. 12, according to an embodiment.

In an embodiment and referring to FIG. 13, the backplane substrate 3002 may include a plurality of display cell areas 3010 and a scribe lane 3020 area disposed between the display cell areas 3010. The display cell areas 3010 may be disposed in a matrix form along the first direction DR1 and the second direction DR2, as illustrated in FIG. 13, and each display cell area 3010 may be individualized into a plurality of display panels 100 (see FIG. 1) through a dicing process after the display manufacturing process is completed. For example, the display cell areas 3010 may be arranged in a matrix form along a first horizontal direction DR1 and a second horizontal direction DR2 perpendicular to the first horizontal direction DR1.

In an embodiment, each of the display cell areas 3010 may include a semiconductor backplane SBP, a light emitting element backplane EBP disposed on the semiconductor backplane SBP, a reflective electrode RL disposed on the light emitting element backplane EBP, and an eleventh insulating film INS11 disposed on the reflective electrode RL. In addition, each of the display cell areas 3010 may include a plurality of electrode patterns, for example, a plurality of anode electrodes AND, disposed on the eleventh insulating film INS11, and the anode electrodes AND may be connected to the reflective electrode RL through a plurality of vias VA10. In this case, the electrode patterns of the display cell areas 3010 may be disposed on the front surface of the backplane substrate 3002, and the substrate chuck 3300 may grip the rear surface of the backplane substrate 3002 so that the electrode patterns of the display cell areas 3010 face downward, i.e., toward the deposition source 3200.

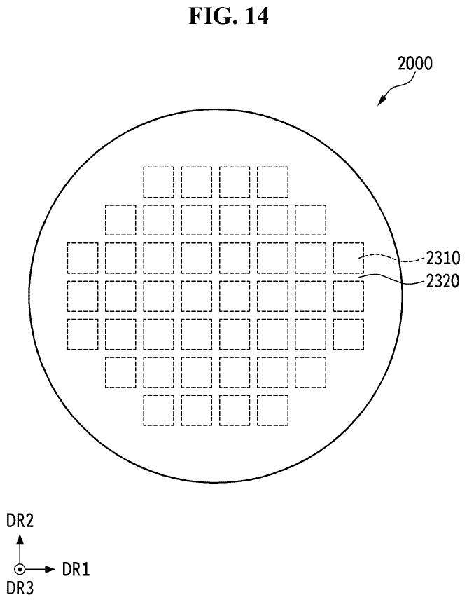

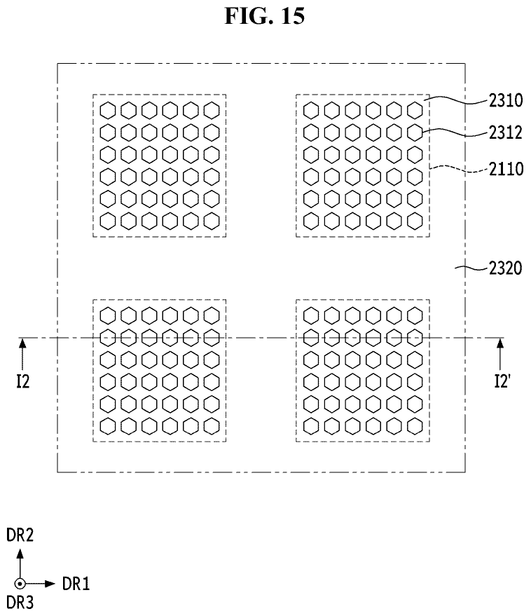

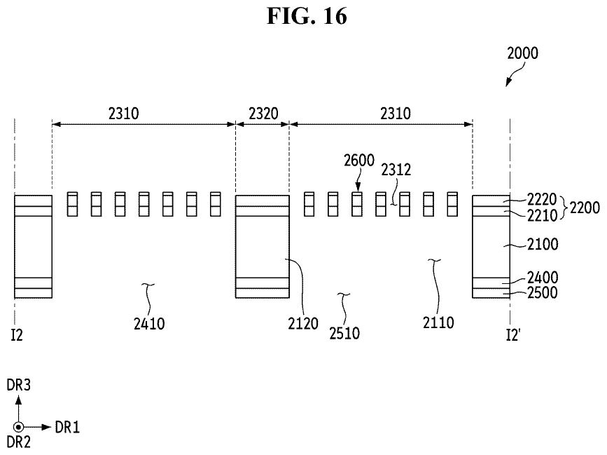

FIG. 14 is a plan view showing a deposition mask, according to an embodiment. FIG. 15 is an enlarged plan view showing mask cell areas illustrated in FIG. 14, according to an embodiment. FIG. 16 is a cross-sectional view showing an embodiment of a deposition mask cut along line I2-I2′ of FIG. 15.

In an embodiment and referring to FIGS. 14 to 16, the deposition mask 2000, according to a first embodiment, may include a mask frame 2100, a membrane 2200, a first rear inorganic film layer 2400, a second rear inorganic film layer 2500, a magnetic layer 2600, and a magnetic plate 2700.

In an embodiment, the mask frame 2100 may have cell openings 2110 and may include lip areas 2120 defining the cell openings 2110. The mask frame 2100 may be provided as a single crystal silicon substrate, and the cell openings 2110 may be formed through a wet etching process using tetramethyl ammonium hydroxide (TMAH) or potassium hydroxide (KOH). A crystal direction of the single crystal silicon substrate provided as the mask frame 2100 may be the third direction DR3.

In an embodiment, the membrane 2200 may be disposed on the mask frame 2100. The membrane 2200 may include mask cell areas 2310 each corresponding to the display cell areas 3010 of the backplane substrate 3002 and a grid area 2320 excluding the mask cell areas 2310.

In an embodiment, the mask cell areas 2310 may be aligned in a matrix form along the first direction DR1 and the second direction DR2, as illustrated in FIG. 14. For example, the mask cell areas 2310 may be aligned in a matrix form along a first horizontal direction DR1 and a second horizontal direction DR2 perpendicular to the first horizontal direction DR1, and may be aligned to each correspond to the display cell areas 3010 of the backplane substrate 3002.

In an embodiment, the grid area 2320 may be an area excluding the mask cell areas 2310 in the membrane 2200. The grid area 2320 may be disposed on an edge of the mask frame 2100 and on the lip area 2120 of the mask frame 2100.

In addition, the membrane 2200 may include an inorganic film layer 2210 and a nitride layer 2220.

In an embodiment, the inorganic film layer 2210 may be disposed on the mask frame 2100. In some embodiments, the inorganic film layer 2210 may be disposed on the mask frame 2100 so that a lower surface thereof is in contact with an upper surface of the mask frame 2100. The inorganic film layer 2210 may be made of a material having an etching selectivity with respect to the nitride layer 2220 and the mask frame 2100. For example, the inorganic film layer 2210 may include silicon oxide (SiOx).

In an embodiment, the nitride layer 2220 may be disposed on the inorganic film layer 2210. In some embodiments, the nitride layer 2220 may be disposed on the inorganic film layer 2210 so that a lower surface thereof is in contact with an upper surface of the inorganic film layer 2210. The nitride layer 2220 may include silicon nitride (SiNx).

In an embodiment, each mask cell area 2310 of the membrane 2200 may include a plurality of pixel openings 2312 that expose the anode electrodes AND during the deposition process. The mask cell areas 2310 may be exposed toward the deposition source 3200 through the cell openings 2110, and the pixel openings 2312 may penetrate through the membrane 2200 and be connected to the cell openings 2110. In some embodiments, the pixel openings 2312 may be formed to penetrate through the inorganic film layer 2210 and the nitride layer 2220 and be connected to the cell openings 2110.

In an embodiment, the first rear inorganic film layer 2400 may be disposed below the mask frame 2100. In some embodiments, the first rear inorganic film layer 2400 may be disposed below the mask frame 2100 so that an upper surface thereof is in contact with a lower surface of the mask frame 2100. First rear openings 2410 in communication with the cell openings 2110 may be formed in the first rear inorganic film layer 2400. The first rear inorganic film layer 2400 may include the same material as the inorganic film layer 2210 of the membrane 2200. For example, the first rear inorganic film layer 2400 may include silicon oxide (SiOx).

In an embodiment, the second rear inorganic film layer 2500 may be disposed below the first rear inorganic film layer 2400. In some embodiments, the second rear inorganic film layer 2500 may be disposed below the first rear inorganic film layer 2400 so that an upper surface thereof is in contact with a lower surface of the first rear inorganic film layer 2400. Second rear openings 2510 in communication with the cell openings 2110 and the first rear openings 2410 may be formed in the second rear inorganic film layer 2500. The second rear inorganic film layer 2500 may include the same material as the nitride layer 2220 of the membrane 2200. For example, the second rear inorganic film layer 2500 may include silicon nitride (SiNx).

In an embodiment, the magnetic layer 2600 may be disposed to cover at least a portion of the membrane 2200. The magnetic layer 2600 may be disposed on the mask cell area 2310 of the membrane 2200. The magnetic layer 2600 may be provided as a plate having a predetermined thickness, and on the mask cell area 2310, may be disposed on the top portion of the nitride layer 2220 of the membrane 2200. In some embodiments, the magnetic layer 2600 may be disposed on the top portion of the nitride layer 2220 so that the lower surface of the magnetic layer 2600 is in contact with the top surface of the nitride layer 2220.

In an embodiment, the pixel openings 2312 formed in the mask cell area 2310 may be extended in the third direction DR3 to penetrate the magnetic layer 2600. In some embodiments, the pixel openings 2312 may be formed to simultaneously penetrate the inorganic film layer 2210 and the nitride layer 2220 of the membrane 2200 and the magnetic layer 2600.

In an embodiment, the thickness of the magnetic layer 2600 may be formed to be thinner than any one of the inorganic film layer 2210 and the nitride layer 2220. For example, the magnetic layer 2600 may be formed in the thickness of about 50 nm to about 100 nm.

In an embodiment, the magnetic layer 2600 may be formed of one metal selected from nickel (Ni), cobalt (Co), and iron (Fe), or be formed of two or more of the metals. In this case, the magnetic layer 2600 may be formed to have a relative magnetic permeability of about 330 or less.

In an embodiment, when the deposition mask 2000 is in contact with the backplane substrate 3002, the above-described magnetic layer 2600 may adhere the mask cell areas 2310 of the membrane 2200 to the backplane substrate 3002 by the magnetic force of a permanent magnet disposed inside the support member 3310 that supports the substrate chuck 3300.

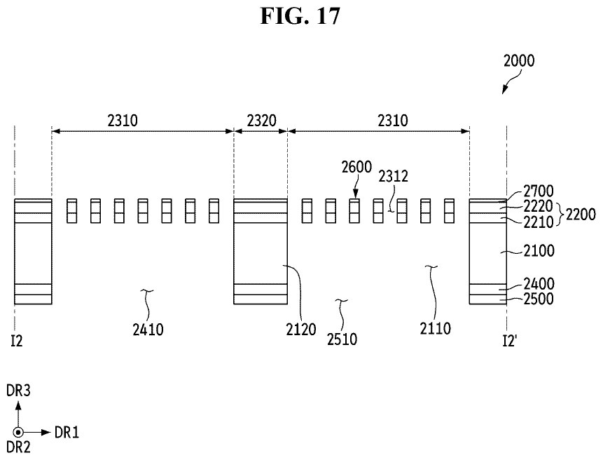

FIG. 17 is a cross-sectional view showing a state in which a magnetic plate is disposed on top of a membrane, according to an embodiment.

In an embodiment and referring to FIG. 17, the magnetic plate 2700 may be arranged to cover at least a portion of the membrane 2200. The magnetic plate 2700 may be disposed on the grid area 2320 of the membrane 2200. The magnetic plate 2700 may be provided as a plate having a predetermined thickness, and on the grid area 2320, may be disposed on the top portion of the nitride layer 2220 of the membrane 2200. In some embodiments, the magnetic plate 2700 may be disposed on the top portion of the nitride layer 2220 so that the lower surface of the magnetic plate 2700 is in contact with the top surface of the nitride layer 2220.

In an embodiment, the thickness of the magnetic plate 2700 may be formed to be thinner than any one of the inorganic film layer 2210 and the nitride layer 2220, and may be formed to correspond to the thickness of the magnetic layer 2600. For example, the magnetic plate 2700 may be formed in the thickness of about 50 nm to about 100 nm.

In addition, in an embodiment, the magnetic plate 2700 may be formed of one metal selected from nickel (Ni), cobalt (Co), and iron (Fe), or be formed of two or more of the metals. In this case, the magnetic plate 2700 may be formed to have a relative magnetic permeability of 330 or less.

In an embodiment, when the deposition mask 2000 is in contact with the backplane substrate 3002, the above-described magnetic plate 2700 may adhere the grid areas 2320 of the membrane 2200 to the backplane substrate 3002 by the magnetic force of a permanent magnet disposed inside the support member 3310 that supports the substrate chuck 3300.

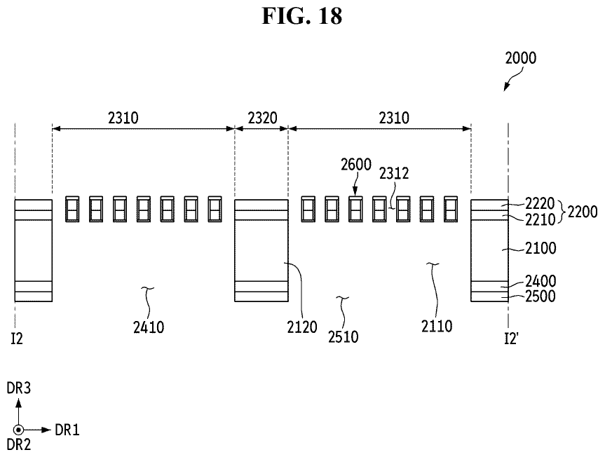

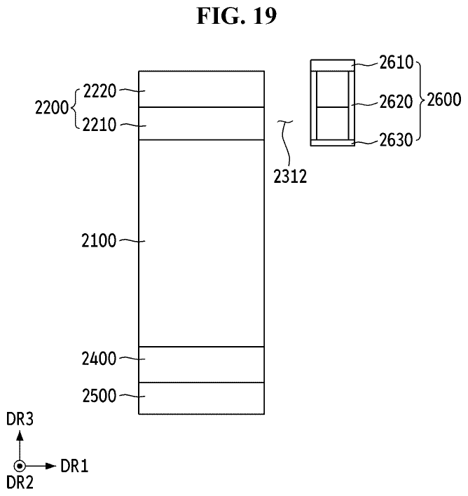

FIG. 18 is a cross-sectional view showing a second embodiment of a deposition mask cut along line I2-I2′ of FIG. 15. FIG. 19 is a partial enlarged view of FIG. 18, according to an embodiment.

Further referring to FIGS. 18 and 19, the deposition mask 2000, according to a second embodiment, may include a mask frame 2100, a membrane 2200, a first rear inorganic film layer 2400, a second rear inorganic film layer 2500, a magnetic layer 2600, and a magnetic plate 2700.

In an embodiment, the mask frame 2100 may have cell openings 2110 and may include lip areas 2120 defining the cell openings 2110. The mask frame 2100 may be provided as a single crystal silicon substrate, and the cell openings 2110 may be formed through a wet etching process using tetramethyl ammonium hydroxide (TMAH) or potassium hydroxide (KOH). A crystal direction of the single crystal silicon substrate provided as the mask frame 2100 may be the third direction DR3.

In an embodiment, the membrane 2200 may be disposed on the mask frame 2100 and may include mask cell areas 2310 each corresponding to the display cell areas 3010 of the backplane substrate 3002 and a grid area 2320 excluding the mask cell areas 2310.

In an embodiment, the mask cell areas 2310 may be aligned in a matrix form along the first direction DR1 and the second direction DR2, as illustrated in FIG. 14. For example, the mask cell areas 2310 may be aligned in a matrix form along a first horizontal direction DR1 and a second horizontal direction DR2 perpendicular to the first horizontal direction DR1 and may be aligned to each correspond to the display cell areas 3010 of the backplane substrate 3002.

In an embodiment, the grid area 2320 may be an area excluding the mask cell areas 2310 in the membrane 2200. The grid area 2320 may be disposed on an edge of the mask frame 2100 and on the lip area 2120 of the mask frame 2100.

In addition, the membrane 2200 may include an inorganic film layer 2210 and a nitride layer 2220.

In an embodiment, the inorganic film layer 2210 may be disposed on the mask frame 2100. In some embodiments, the inorganic film layer 2210 may be disposed on the mask frame 2100 so that a lower surface thereof is in contact with an upper surface of the mask frame 2100. The inorganic film layer 2210 may be made of a material having an etching selectivity with respect to the nitride layer 2220 and the mask frame 2100. For example, the inorganic film layer 2210 may include silicon oxide (SiOx).

In an embodiment, the nitride layer 2220 may be disposed on the inorganic film layer 2210. In some embodiments, the nitride layer 2220 may be disposed on the inorganic film layer 2210 so that a lower surface thereof is in contact with an upper surface of the inorganic film layer 2210. The nitride layer 2220 may include silicon nitride (SiNx).

In an embodiment, each mask cell area 2310 of the membrane 2200 may include a plurality of pixel openings 2312 that expose the anode electrodes AND during the deposition process. The mask cell areas 2310 may be exposed toward the deposition source 3200 through the cell openings 2110, and the pixel openings 2312 may penetrate through the membrane 2200 and be connected to the cell openings 2110. In some embodiments, the pixel openings 2312 may be formed to penetrate through the inorganic film layer 2210 and the nitride layer 2220 and be connected to the cell openings 2110.

In an embodiment, the first rear inorganic film layer 2400 may be disposed below the mask frame 2100. In some embodiments, the first rear inorganic film layer 2400 may be disposed below the mask frame 2100 so that an upper surface thereof is in contact with a lower surface of the mask frame 2100. First rear openings 2410 in communication with the cell openings 2110 may be formed in the first rear inorganic film layer 2400. The first rear inorganic film layer 2400 may include the same material as the inorganic film layer 2210 of the membrane 2200. For example, the first rear inorganic film layer 2400 may include silicon oxide (SiOx).

In an embodiment, the second rear inorganic film layer 2500 may be disposed below the first rear inorganic film layer 2400. In some embodiments, the second rear inorganic film layer 2500 may be disposed below the first rear inorganic film layer 2400 so that an upper surface thereof is in contact with a lower surface of the first rear inorganic film layer 2400. Second rear openings 2510 in communication with the cell openings 2110 and the first rear openings 2410 may be formed in the second rear inorganic film layer 2500. The second rear inorganic film layer 2500 may include the same material as the nitride layer 2220 of the membrane 2200. For example, the second rear inorganic film layer 2500 may include silicon nitride (SiNx).

In an embodiment, the magnetic layer 2600 may be disposed to surround the membrane 2200 so that at least a portion of the magnetic layer 2600 is in contact with the pixel opening 2312. The magnetic layer 2600 may be disposed on the mask cell area 2310 of the membrane 2200. The magnetic layer 2600 may include a first magnetic layer 2610, a second magnetic layer 2620, and a third magnetic layer 2630.

In an embodiment, the first magnetic layer 2610 may be provided as a plate having a predetermined thickness, and on the mask cell area 2310, may be disposed on the top portion of the nitride layer 2220 of the membrane 2200. In some embodiments, the magnetic layer 2600 may be disposed on the top portion of the nitride layer 2220 so that the lower surface of the magnetic layer 2600 is in contact with the top surface of the nitride layer 2220.

In an embodiment, the thickness of the first magnetic layer 2610 may be formed to be thinner than any one of the inorganic film layer 2210 and the nitride layer 2220. For example, the first magnetic layer 2610 may be formed in the thickness of about 50 nm to about 100 nm. The thickness of the first magnetic layer 2610 may be thicker than the thickness of each of the second magnetic layer 2620 and the third magnetic layer 2630.

In addition, the first magnetic plate 2610 may be formed of one metal selected from nickel (Ni), cobalt (Co), and iron (Fe), or be formed of two or more of the metals. In this case, the first magnetic plate 2610 may be formed to have a relative magnetic permeability of 330 or less.

In an embodiment, the second magnetic layer 2620 may be disposed to extend in the lower direction from the first magnetic layer 2610 and surround the side surface of the membrane 2200. In some embodiments, the second magnetic layer 2620 may be extended in the third direction DR3 from the first magnetic layer 2610 to surround the side surface of the membrane 2200 so to be in contact with the pixel openings 2312. The thickness of the second magnetic layer 2620 may be thinner than the thickness of the first magnetic layer 2610.

In addition, the second magnetic plate 2620 may be formed of one metal selected from nickel (Ni), cobalt (Co), and iron (Fe), or be formed of two or more of the metals. In this case, the second magnetic plate 2620 may be formed to have a relative magnetic permeability of about 330 or less.

In an embodiment, the third magnetic layer 2630 may be provided as a plate having a predetermined thickness, and on the mask cell area 2310, may be disposed on the lower portion of the inorganic film layer 2210 of the membrane 2200. In some embodiments, the third magnetic layer 2630 may be disposed on the lower portion of the inorganic film layer 2210 so that the top surface of the third magnetic layer 2630 is in contact with the lower surface of the inorganic film layer 2210. The third magnetic layer 2630 may be connected with the second magnetic layer 2620 to surround the lower surface of the membrane 2200. The thickness of the third magnetic layer 2630 may be thinner than the thickness of the first magnetic layer 2610.

In addition, the third magnetic layer 2630 may be formed of one metal selected from nickel (Ni), cobalt (Co), and iron (Fe), or be formed of two or more of the metals. In this case, the third magnetic layer 2630 may be formed to have a relative magnetic permeability of 330 or less.

As described above, when the deposition mask 2000 is in contact with the backplane substrate 3002, the magnetic layer 2600 including the first to third magnetic layers 2610 to 2630 may adhere the mask cell areas 2310 of the membrane 2200 to the backplane substrate 3002 by a magnetic force of a permanent magnet disposed inside the support member 3310 that supports the substrate chuck 3300.

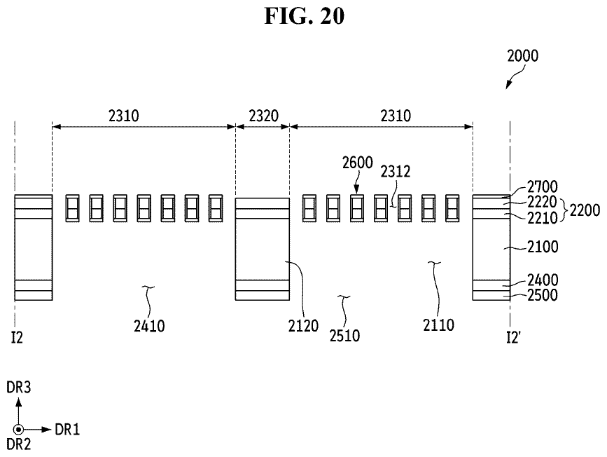

FIG. 20 is a cross-sectional view showing a state in which the magnetic plate is disposed on top of the membrane in FIG. 18, according to an embodiment.

In an embodiment and referring to FIG. 20, the magnetic plate 2700 may be disposed to cover at least a portion of the membrane 2200. The magnetic plate 2700 may be disposed on the grid area 2320 of the membrane 2200. The magnetic plate 2700 may be provided as a plate having a predetermined thickness, and on the grid area 2320, may be disposed on the top portion of the nitride layer 2220 of the membrane 2200. In some embodiments, the magnetic plate 2700 may be disposed on the top portion of the nitride layer 2220 so that the lower surface of the magnetic plate 2700 is in contact with the top surface of the nitride layer 2220.

In an embodiment, the thickness of the magnetic plate 2700 may be formed to be thinner than any one of the inorganic film layer 2210 and the nitride layer 2220, and may be formed to correspond to the thickness of the first magnetic layer 2610. For example, the magnetic plate 2700 may be formed in the thickness of about 50 nm to about 100 nm.

In addition, the magnetic plate 2700 may be formed of one metal selected from nickel (Ni), cobalt (Co), and iron (Fe), or be formed of two or more of the metals. In this case, the magnetic plate 2700 may be formed to have a relative magnetic permeability of 330 or less.

In an embodiment, when the deposition mask 2000 is in contact with the backplane substrate 3002, the above-described magnetic plate 2700 may adhere the grid areas 2320 of the membrane 2200 to the backplane substrate 3002 by the magnetic force of a permanent magnet disposed inside the support member 3310 that supports the substrate chuck 3300.

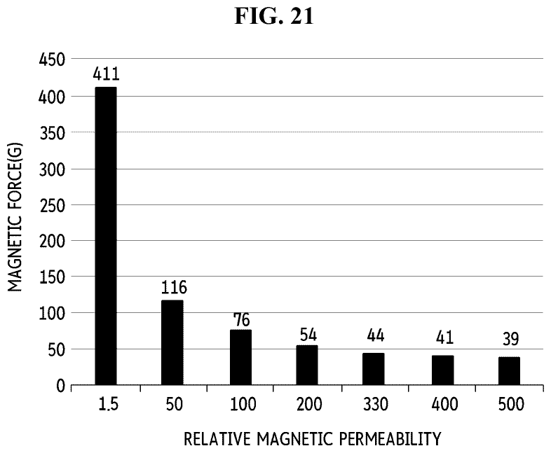

FIG. 21 is a graph showing magnetic force generated compared to the relative magnetic permeability of a magnetic layer of the deposition mask, according to an embodiment.

In an embodiment and referring to FIG. 21, when the relative magnetic permeability of the magnetic layer 2600 is about 1.5, the magnetic force generated in the magnetic layer 2600 is about 411 G; when the relative magnetic permeability of the magnetic layer 2600 is about 50, the magnetic force generated in the magnetic layer 2600 is about 116 G; when the relative magnetic permeability of the magnetic layer 2600 is about 100, the magnetic force generated in the magnetic layer 2600 is about 76 G; when the relative magnetic permeability of the magnetic layer 2600 is about 200, the magnetic force generated in the magnetic layer 2600 is about 54 G; and when the relative magnetic permeability of the magnetic layer 2600 is about 330, the magnetic force generated in the magnetic layer 2600 is about 44 G. Further, when the relative magnetic permeability of the magnetic layer 2600 is about 400, the magnetic force generated in the magnetic layer 2600 is about 41 G, and when the relative magnetic permeability of the magnetic layer 2600 is about 500, the magnetic force generated in the magnetic layer 2600 is about 39 G.

In an embodiment, since the mask cell areas 2310 of the membrane 2200 can be brought into close contact with the backplane substrate 3002 only when the magnetic force generated in the magnetic layer 2600 is about 44G or more, the magnetic layer 2600 may be formed to have the relative magnetic permeability of about 330 or less.

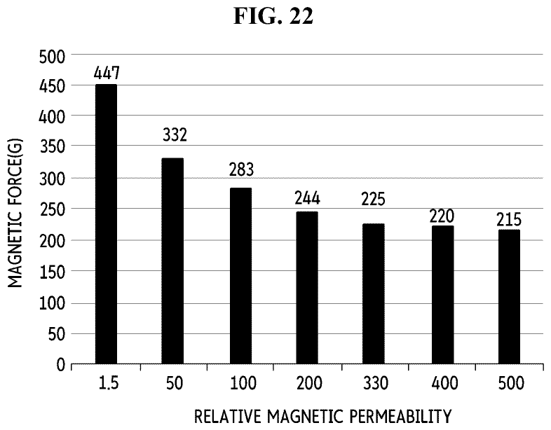

FIG. 22 is a graph showing magnetic force generated compared to the relative magnetic permeability of a magnetic plate of the deposition mask, according to an embodiment.

In an embodiment and referring to FIG. 22, when the relative magnetic permeability of the magnetic plate 2700 is about 1.5, the magnetic force generated in the magnetic plate 2700 is about 447 G; when the relative magnetic permeability of the magnetic plate 2700 is about 50, the magnetic force generated in the magnetic plate 2700 is about 332 G; when the relative magnetic permeability of the magnetic plate 2700 is about 100, the magnetic force generated in the magnetic plate 2700 is about 283 G; when the relative magnetic permeability of the magnetic plate 2700 is about 200, the magnetic force generated in the magnetic plate 2700 is about 244 G; and when the relative magnetic permeability of the magnetic plate 2700 is about 330, the magnetic force generated in the magnetic plate 2700 is about 225 G. Further, when the relative magnetic permeability of the magnetic plate 2700 is about 400, the magnetic force generated in the magnetic plate 2700 is about 220 G, and when the relative magnetic permeability of the magnetic plate 2700 is about 500, the magnetic force generated in the magnetic plate 2700 is about 215 G.

Since the grid areas 2320 of the membrane 2200 can be brought into close contact with the backplane substrate 3002 only when the magnetic force generated in the magnetic plate 2700 is about 225 G or more, the magnetic plate 2700 may be formed to have the relative magnetic permeability of about 330 or less.

The display device, according to an embodiment, can be applied to various electronic devices. The electronic device, according to an embodiment, includes the display device described above, and may further include modules or devices having additional functions in addition to the display device.

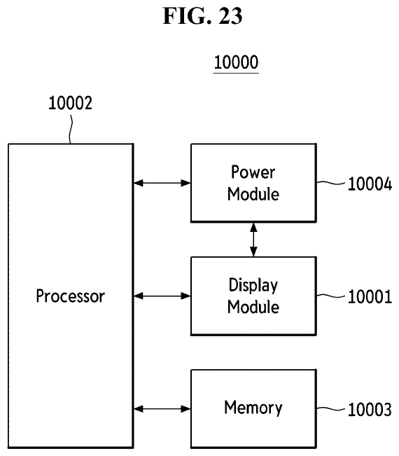

FIG. 23 is a block diagram of an electronic device, according to an embodiment.

In an embodiment and referring to FIG. 23, the electronic device 10000, according to an embodiment, may include a display module 10001, a processor 10002, a memory 10003, and a power module 10004.

In an embodiment, the processor 10002 may include at least one of a central processing unit (CPU), an application processor (AP), a graphic processing unit (GPU), a communication processor (CP), an image signal processor (ISP), and a controller.

In an embodiment, the memory 10003 may store data information necessary for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

In an embodiment, the power module 10004 may include a power supply module such as, for example a power adapter or a battery, and a power conversion module that converts the power supplied by the power supply module to generate power necessary for the operation of the electronic device 10000.

At least one of the components of the electronic device 10000, according to an embodiment may be included in the display device. In addition, some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

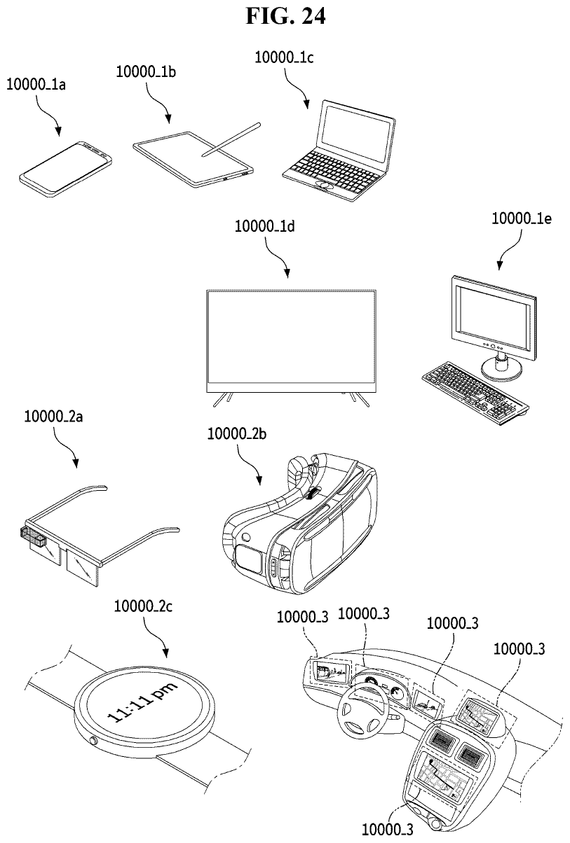

FIG. 24 is a diagram of an electronic device, according to various embodiments.

Referring to FIG. 24, various electronic devices to which display devices, according to embodiments, are applied may include not only image display electronic devices such as a smart phone 10000_1a, a tablet PC (personal computer) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a CID (Center Information Display) and a room mirror display arranged on a dashboard, center fascia, and dashboard of an automobile.

It should be understood, however, that the aspects and features of the invention are not restricted to the one set forth herein. The above and other aspects of the invention will become more apparent to one of ordinary skill in the art to which the invention pertains, with equivalents thereof to be included therein.

What is claimed is:

1. A deposition mask comprising:
a mask frame in which a cell opening is formed;
a membrane disposed on top of the mask frame; and
a magnetic layer disposed to cover at least a portion of the membrane.

2. The deposition mask of claim 1,
wherein the membrane is partitioned within a mask cell area disposed on a top portion of the cell opening, and a grid area disposed on a top portion of the mask frame except the cell opening, and
the magnetic layer is disposed on the mask cell area.

3. The deposition mask of claim 2,
wherein, in the mask cell area, a plurality of pixel openings penetrating the membrane and the magnetic layer is formed.

4. The deposition mask of claim 2,
wherein the membrane comprises:
an inorganic film layer disposed on the top portion of the mask frame; and
a nitride layer disposed on a top portion of the inorganic film layer,
wherein the magnetic layer is disposed on a top portion of the nitride layer.

5. The deposition mask of claim 4,
wherein a thickness of the magnetic layer is thinner than a thickness of the inorganic film layer or a thickness of the nitride layer.

6. The deposition mask of claim 1,
wherein the magnetic layer is formed in a thickness of about 50 nm to about 100 nm.

7. The deposition mask of claim 1,
wherein the magnetic layer includes at least one or more of nickel (Ni), cobalt (Co), and iron (Fe).

8. The deposition mask of claim 1,
wherein the magnetic layer has a relative magnetic permeability of about 330 or less.

9. The deposition mask of claim 4,
further comprising a magnetic plate disposed to cover at least a portion of the membrane, in the grid area.

10. The deposition mask of claim 9,
wherein the magnetic plate is disposed on the top portion of the nitride layer.

11. The deposition mask of claim 9,
wherein a thickness of the magnetic plate is thinner than a thickness of the inorganic film layer or a thickness of the nitride layer.

12. The deposition mask of claim 9,
wherein the magnetic plate is formed in a thickness of about 50 nm to about 100 nm.

13. The deposition mask of claim 9,
wherein a thickness of the magnetic plate corresponds to a thickness of the magnetic layer.

14. The deposition mask of claim 9, wherein at least one of,
the magnetic plate includes at least one or more of nickel (Ni), cobalt (Co), and iron (Fe), and
the magnetic plate has a relative magnetic permeability of about 330 or less.

15. The deposition mask of claim 2,
wherein,
in the mask cell area, a plurality of pixel openings penetrating the membrane is formed, and
the magnetic layer surrounds the membrane so that a portion thereof is in contact with the pixel opening.

16. The deposition mask of claim 15,
wherein the membrane comprises:
an inorganic film layer disposed on the top portion of the mask frame; and
a nitride layer disposed on the top portion of the inorganic film layer,
wherein the magnetic layer comprises:
a first magnetic layer disposed on a top portion of the nitride layer;
a second magnetic layer which extends from the first magnetic layer to the lower portion; and
a third magnetic layer disposed on a lower portion of the inorganic film layer and connected to the second magnetic layer.

17. The deposition mask of claim 16,
wherein a thickness of the first magnetic layer is thicker than a thickness of the second magnetic layer or a thickness of the third magnetic layer.

18. The deposition mask of claim 16,
further comprising a magnetic plate, disposed on a top portion of the nitride layer, in the grid area,
wherein the thickness of the magnetic plate corresponds to a thickness of the first magnet layer.

19. The deposition mask of claim 1, further comprising:
a first rear inorganic film layer disposed on a lower portion of the mask frame and in which a first rear opening is formed; and
a second rear inorganic film layer disposed on a lower portion of the first rear inorganic film layer and in which a second rear opening is formed,
wherein the first rear opening and the second rear opening are disposed on the cell opening.

20. An electronic device comprising:
a display device manufactured by a deposition mask;
the deposition mask comprising:
a mask frame in which a cell opening is formed;
a membrane disposed on top of the mask frame; and
a magnetic layer disposed to cover at least a portion of the membrane.
